(19) United States
(12) Patent Application Publication
(10) Pub. No.: US 2008/0023065 A1
(43) Pub. Date: Jan. 31, 2008

(54) Thin film photovoltaic module wiring for improved efficiency

(76) Inventors: Peter G. Borden, San Mateo, CA (US); David J. Eaglesham, Livermore, CA (US)

Correspondence Address: Applied Materials, Inc., P.O. Box 450A, Santa Clara, CA, 95052, US

(21) Appl. No.: 11/492,277

(22) Filed: Jul. 25, 2006

(51) Int. Cl. H01L 31/00

(52) U.S. Cl. 136/256

(57) ABSTRACT

The present invention relates to configuring and wiring together cells in TF PV modules. According to one aspect, cells are fabricated on one plane on a top surface of a substrate, with wiring patterned on a parallel plane, and vias formed to provide connections between the cell plane and wiring plane. In one embodiment, the wiring plane is on the back surface of the substrate and vias are formed through the substrate. In another embodiment, the wiring plane is on the top surface of the substrate underneath the cell plane and an insulating layer, with the vias formed through the insulating layer. In another embodiment, the cell plane formed on the top surface includes superstrate cells that are illuminated through a transparent substrate, with an insulator between the cell plane and an upper wiring plane. According to another aspect, the heavy bus bar connections in the wiring plane can carry large currents and do not block light impinging on the cells. According to further aspects, the wiring plane enables use of parallel cell connections that provide immunity to shading, as described above. Moreover, these connections can be wired in a variety of methods, allowing use of series-parallel arrangements so that, for example, local regions could be parallel connected while larger regions series connected.

### FIELD OF THE INVENTION

The present invention relates to methods for making interconnections used in thin film photovoltaic (TF PV) modules, and more particularly to improved interconnections that are provided on a plane parallel to a top surface where the cells are provided.

### BACKGROUND OF THE INVENTION

TF PV modules offer many advantages over other types of photovoltaic modules such as modules based on silicon wafers, such as lower manufacturing cost and less consumption of materials with limited availability. However, TF PV modules suffer from certain drawbacks such as incompatibility with other system components, degradation over time, losses due to shading and non-uniformities, and lower efficiency. As a result, despite their inherent advantages, TF PV modules enjoy only about a 10% share of the market as compared to about a 90% share for silicon modules.

To illustrate the conventional drawbacks even further, a conventional method for forming and configuring a TF PV module is described as follows. Thin film material layers are deposited on the surface of a large substrate, typically glass. During this process, a set of scribes are made at regular spacing, most commonly using lasers, but occasionally using mechanical scribing. The combination of the scribes and successive depositions form long series-connected photovoltaic regions.

As shown in FIG. 1A, the large glass substrate is then cut into sections, which may be on the order of about 150×80 cm, to form modules 100. Using laser scribing for example, the film is also removed from the surface of the substrate around the periphery to isolate the cells 102 from the edge. Finally, terminals 104 are bonded to the end cells 102-L and 102-R.

The series connections between cells 102 is desirable because it reduces the operating current by the number of cells. For example, a 1 m² module at an efficiency of 10% might generate 100 watts of power. At a typical operating voltage of 0.9 volts, this would require a current of 110 amps, far in excess of what the thin film conductors can carry without suffering excess ohmic losses. Dividing the module into 100 cells, each 1 cm wide, reduces the current to 1.1 amps and cuts the ohmic loss (═I²R) by 10,000 times.

The series connection between cells, however, also introduces some limitations. As shown in FIG. 1B, each cell 102 can be viewed as a diode 110 with a current generator 112. For simplicity, this model neglects resistance elements. As shown, the cells are connected in series during the formation process. The photocurrent generated in the n^{th} cell is I_{Ln}. If all cells generate exactly the same photocurrent, then the module delivers this current at the output terminals. However, if one of the cells in the series string generates less current, it will limit the current that the module delivers. This can result from a variety of factors such as shadowing. For example, at the start and end of the day objects cast long shadows that may non-uniformly fall on a module. Other factors include process variation (for example, non-uniformity in a deposition system) and degradation over time. As for process variation, it is well known that small modules typically have higher efficiency than large modules, because it is much easier to achieve good uniformity in a small area than a large area, so that small modules have less current limiting variation than large modules.

However it is caused, this current limitation can also damage the module. Normally, PV cells operate in forward bias. If one cell in a string is current limited because of shading, for example, then that cell may become reverse biased to a point that it conducts in the reverse direction (i.e., the cell is driven into reverse breakdown). Excess reverse bias can damage that cell. For this reason, modules using silicon wafers have built-in protect diodes. However, it is difficult to install such diodes within thin film modules, as it is not easy to form terminals for such diodes using laser scribing.

Another problem hindering the adoption of conventional TF PV modules is that in practice, there are limitations on the size, shape and nature of the interconnect regions between cells. Because laser scribing causes edge damage, it is preferred to make the width of each cell relatively large—on the order of a centimeter. Making narrower cells would also require more scribing time and increase cost. Also, scribing is an ablative process, so it is easiest to make long, straight cuts and most difficult to make contact pads, regions exposing under-layers, or regions with complex, 2-dimensional shapes.

Co-pending application No. ______ (AMAT-010937), commonly owned by the present assignee, the contents of which are incorporated by reference, dramatically advanced the state of the art by disclosing improved methods for configuring TF PV modules, including dividing a module into sub-modules and wiring the sub-modules together in parallel and/or series-parallel combinations. These techniques improved module performance in the face of such adverse conditions as process non-uniformity and shading. An aspect of the co-pending application is that photolithography and etch and deposition processes such as those described in co-pending application Ser. Nos. 11/394,723 and 11/395,080 can be used to divide and form series interconnections in the module, and further to divide the module into sub-modules. Such processes make it possible to form much narrower cells and thereby facilitating such unique module intraconnections.

The following illustrates certain advantages provided by the co-pending application even further. Consider, for example, the simple series and parallel arrangements of cells modeled on PSPICE shown in FIGS. 2A and 2B. The circuit in FIG. 2A is a series connection of ten cells, the last of which is ⅔ shaded, so that its normal current is ⅓ that of the other cells. The IV curve above the schematic in FIG. 2A is for this circuit. The circuit in FIG. 2B contains the same ten cells connected in parallel, with its IV curve also shown above the circuit diagram. Note that the series-connected module has a degraded IV characteristic, whereas the parallel-connected module has a normal IV characteristic.

Similar results are observed by estimating the power as a function of voltage for both of these configurations. With no shading, both have the same estimated power of 42.5 mW. As shown in FIG. 3, with the ⅔ shading, the series-connected module output power degrades 24%, while the parallel-connected module degrades 7%. Therefore, there is a significant reduction in losses from causes such as shading and current-reducing defects through the use of a parallel configuration as described in the co-pending application.

Although employing parallel connections provide benefits compared to completely series-connected modules, such benefits can prove fleeting. For example, it may be difficult to provide parallel wiring between sub-modules on the same side of the glass substrate as the active regions. Such wiring can block light, thereby reducing the potential benefits of the parallel wiring. Moreover, the parallel wiring needs to accommodate potentially more current in a more confined area than occurs in across a fully series-connected module, which requires larger bus structures, which can also reduce or block the active areas. Still further, increased current makes potential resistive losses even more important to consider, and so such wiring should not introduce additional resistance.

Accordingly, a wiring scheme is needed that can fully unleash the benefits of the TF PV module configuration and intraconnection techniques of the co-pending application.

### SUMMARY OF THE INVENTION

The present invention relates to configuring and wiring together cells in TF PV modules. According to one aspect, cells are fabricated on one plane on a top surface of a substrate, with wiring patterned on a parallel plane, and vias formed to provide connections between the cell plane and wiring plane. In one embodiment, the wiring plane is on the back surface of the substrate and vias are formed through the substrate. In another embodiment, the wiring plane is on the top surface of the substrate underneath the cell plane and an insulating layer, with the vias formed through the insulating layer. In another embodiment, the cell plane formed on the top surface includes superstrate cells that are illuminated through a transparent substrate, with an insulator between the cell plane and an upper wiring plane. According to another aspect, the heavy bus bar connections in the wiring plane can carry large currents and do not block light impinging on the cells. According to further aspects, the wiring plane enables use of parallel cell connections that provide immunity to shading, as described above. Moreover, these connections can be wired in a variety of methods, allowing use of series-parallel arrangements so that, for example, local regions could be parallel connected while larger regions series connected. According to still further aspects of the invention, once the substrate is prepared using plating and methods similar to those employed in printed circuit board manufacture, the fabrication process may require only two laser scribes, rather than the conventional three. This reduces line width, as fewer scribes must be registered to one another, as well as reducing process complexity. Unlike the prior art process, the scribes do not require selectivity, and can be done from the front. According to additional aspects of the invention, the back side wiring plane embodiment can also accommodate other components and structures such as protect diodes, switches and processors.

### BRIEF DESCRIPTION OF THE DRAWINGS

These and other aspects and features of the present invention will become apparent to those ordinarily skilled in the art upon review of the following description of specific embodiments of the invention in conjunction with the accompanying figures, wherein:

FIGS. 1A & 1B illustrate interconnections in a conventional TF PV module;

FIGS. 2A and 2B illustrate I-V characteristics of photovoltaic cells wired together in series and parallel, respectively, and subject to shading;

FIG. 3 is a graph comparing power output and shading loss in parallel-connected and series-connected cells;

FIGS. 4A and 4B illustrate an example implementation of a module employing vias and back side wiring in accordance with the invention;

FIGS. 5A to 5F illustrate an example fabrication process for a module including vias and back-side wiring in accordance with the invention;

FIGS. 6A to 6D illustrate a module divided into sub-modules that are wired together using back-side wiring in accordance with certain aspects of the invention;

FIG. 7 illustrate how additional components such as protect diodes can be incorporated in back-side wiring according to certain aspects of the invention;

FIGS. 8A and 8B illustrate how a combination of top surface and back surface wiring can be employed in a module configured according to certain aspects of the invention;

FIGS. 9A and 9B illustrate a first alternative embodiment for providing different cell layers and wiring layers connected with vias in accordance with the principles of the invention; and

FIGS. 10A and 10B illustrate a second alternative embodiment for providing different cell layers and wiring layers connected with vias in accordance with the principles of the invention.

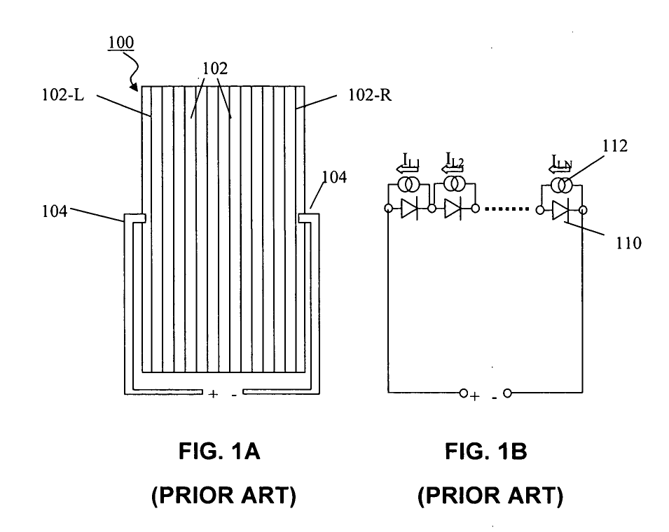

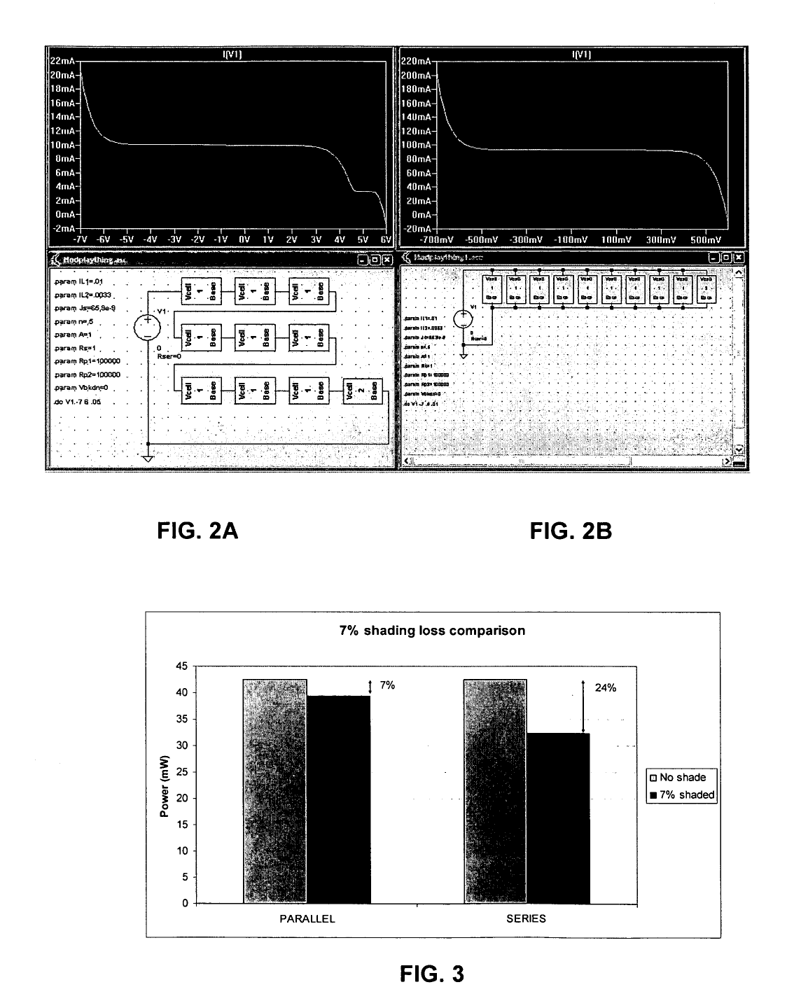

### DESCRIPTION OF REFERENCE NUMERALS ON THE DRAWINGS

The following listing of reference numerals used in the drawings is intended to be illustrative rather than limiting, and the corresponding descriptions are not intended in any way to provide express definitions of any terms used in the specification, unless otherwise explicitly set forth in the foregoing descriptions. Those skilled in the art will appreciate various substitutions and modifications to the elements in the drawings after being taught by the present invention.

| | |
|---|---|
| 100 | module |
| 102 | cell |
| 104 | terminal |
| 110 | diode |
| 112 | current generator |
| 400 | module |
| 402 | cell |
| 404 | substrate |
| 412 | metal layer |
| 414 | semiconducting layer |
| 416 | transparent conducting layer |
| 420 | isolation region |
| 422 | via |
| 424 | bus |
| 430 | gap |
| 502 | molded thin area |
| 600 | module |
| 602 | sub-module |
| 604 | set |
| 606 | first common node |
| 608 | second common node |
| 610 | bus |
| 622 | via |
| 702 | protect diode |
| 800 | module |
| 802 | sub-module |
| 806 | set |
| 810 | first common node |
| 812 | second common node |
| 820 | output bus |
| 902 | substrate |
| 904 | wiring layer |
| 906 | cell layer |
| 908 | insulating layer |
| 910 | via |
| 1002 | substrate |
| 1004 | cell layer |
| 1006 | wiring layer |
| 1008 | insulating layer |
| 1010 | via |

### DETAILED DESCRIPTION OF THE PREFERRED EMBODIMENTS

The present invention will now be described in detail with reference to the drawings, which are provided as illustrative examples of the invention so as to enable those skilled in the art to practice the invention. Notably, the figures and examples below are not meant to limit the scope of the present invention to a single embodiment, but other embodiments are possible by way of interchange of some or all of the described or illustrated elements. Moreover, where certain elements of the present invention can be partially or fully implemented using known components, only those portions of such known components that are necessary for an understanding of the present invention will be described, and detailed descriptions of other portions of such known components will be omitted so as not to obscure the invention. In the present specification, an embodiment showing a singular component should not be considered limiting; rather, the invention is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present invention encompasses present and future known equivalents to the known components referred to herein by way of illustration.

Generally, the present invention enables configuration of TF PV modules through the use of via connections to access wiring in a plane separate from that used for the photovoltaic cells. This novel element provides a number of advantages It enables use of heavy bus bar connections that do not block light. Because of their low series resistance, these connections can carry large currents without suffering ohmic losses, enabling use of parallel cell connections that provide immunity to shading, as described above. These connections can be wired in a variety of methods, allowing use of series-parallel arrangements so that, for example, local regions could be parallel connected while larger regions series connected.

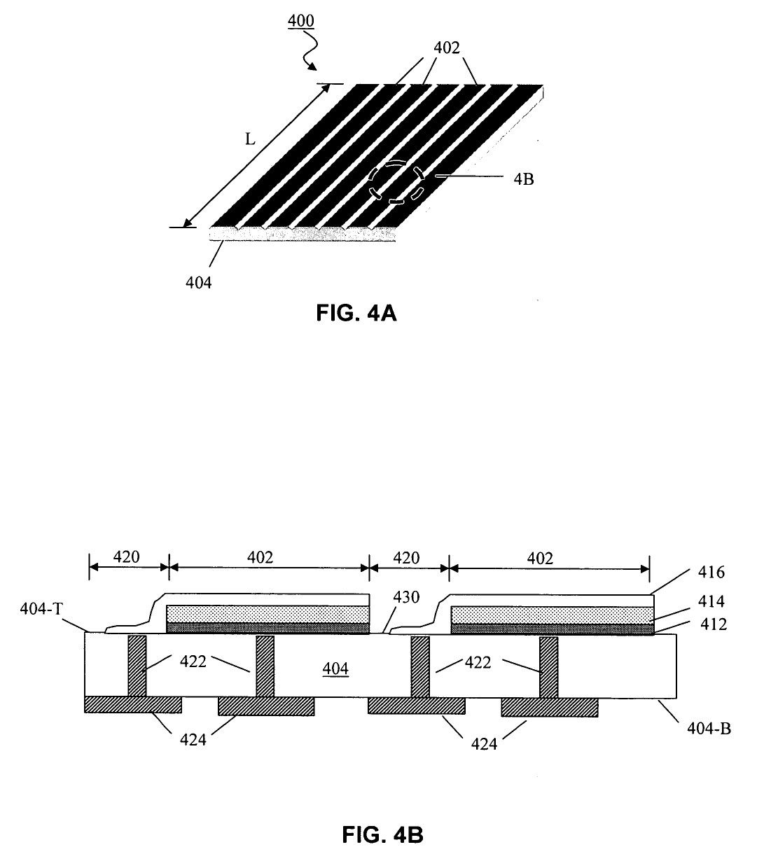

An example implementation of certain embodiments of the invention is illustrated in FIGS. 4A and 4B.

As shown in FIG. 4A, module 400 includes cells 402 formed on a top surface of a substrate 404. In this example implementation, cells 402 run the entire length L of the module as is typical of conventional TF PV modules. Other alternative configurations such as that made possible by the teachings of the co-pending application No. ______ (AMAT-010937), as well as the wiring methods of the present invention, will be described in more detail below. Moreover, although only a few cells 402 are shown in this drawing for ease of illustration, there may be hundreds.

FIG. 4B is an enlarged cross-sectional view of a portion of module 400 as shown in FIG. 4A. As shown in FIG. 4B, cells 402 are comprised of a photovoltaic material stack 412-416 deposited on the substrate 404, which in some embodiments may be a 5 mm thick sheet of glass. In other embodiments, substrate 404 may be a polymer material, or one or more layers of material such as stainless steel or molybdenum foil. In one example, layer 412 is a metal such as molybdenum, layer 414 is a semiconductor such as CIGS, and layer 416 is a TCO such as ZnO. In some embodiments, the entire stack is about 2-3 μm thick. It should be appreciated that the stack 412-416 can include additional layers such as buffer layers and insulators, and additional insulating layers may be used if substrate 404 is conductive, but details thereof are omitted here so as not to obscure the invention.

Cells 402 can be about 1 cm wide and are separated by isolation regions 420, which can be about 30 μm wide. In contrast to the prior art, cells 402 are not interconnected on the top surface 404-T of substrate 404, such as by connecting the top conducting layer 416 of one cell to the metal layer 412 of an adjacent cell. Rather, cell interconnections are made using wiring provided on the back surface 404-B of substrate 404. Accordingly, gaps 430 about 10 μm wide completely separate adjacent cells on the top surface 404-T of substrate 404.

More particularly, as shown in FIG. 4B, vias 422 through substrate 404 connect features on the top surface 404-T of substrate 404 to busses 424 on the back surface 404-B of substrate 404. In this example, the vias 422 provide two separate connections per cell 402, one connection to the metal layer 412, and the other connection to the portion of layer 416 of each cell 402 that extends into the isolation region 420 and onto the top surface 404-T of substrate 404. In this cross-sectional drawing in FIG. 4B, only two vias 422 per cell are shown, however, there can be many dozens or hundreds spaced apart in the substrate 404 along the entire length L of each cell.

Vias 422 can have circular cross-sections, having a radius of about 10-50 μm, and be filled with a highly conductive material such as plated nickel or copper. Note that region 420 may not be of constant width, but may have cutouts at the sites of vias to accommodate vias with a larger diameter than the width of the isolation region 420, in order to provide a lower via resistance. It should be further noted that where the substrate 404 is a metal, the vias can contain an insulator material to isolate the via connection from the substrate.

Busses 424 can comprised of Ni or Cu having a thickness of about 5-50 μm and a width of about 0.1 to 1 cm. Although not shown in detail in FIG. 4B, busses 424 can be patterned on back surface 404-B of substrate 404 using printed circuit board techniques to provide interconnections between cells. As should be appreciated, depending on how busses 424 are patterned to be connected together, any combination of parallel and series connections between cells 402 can be accomplished. Busses such as 424 allow higher current because they can be made much thicker than the metal layer under the cells. For example, considerations such as differential thermal expansion and surface morphology can limit the thickness of the metal layer under the cells, especially if the cells must be processed at elevated temperatures. In addition, busses such as 424 can be wired differently than the cells to provide, for example, interconnects between cells or between regions of the module.

The spacing of vias is selected to minimize resistive losses. The resistance Rᵥ of a via is determined by

$${R}_{V} = \frac{ρ {t}_{s}}{π {r}_{v}^{2}} ,$$

where ρ is the metal resistivity, tₛ is the substrate thickness, and rᵥ is the via radius. For a 50 μm diameter nickel-filled via in 5 mm thick glass, ρ=7×10⁻⁶ Ω-cm and R_{V}=0.18Ω.

The current through a via is equal to the current produced by a rectangular portion of the cell stripe of dimensions W_{C} x (the via spacing S). This current is

$${I}_{V} = {W}_{C} S \frac{η {P}_{sun}}{{V}_{mp}} ,$$

where η is the cell efficiency, Pₛᵤₙ is the insolation (0.1 W/cm² at AM 1.5), and Vₘₚ is the cell voltage at the maximum power point. For Vₘₚ=0.6 volts, η=10%, W_{C}=1 cm, I_{V}=0.117×S amps.

If the voltage drop I_{V}R_{V} across the via is desired to be less than 0.5% of the operating voltage, then the spacing should be S=1 cm. Accordingly, for a module with 1 cm cell stripes, there will be about 10,000 vias/m².

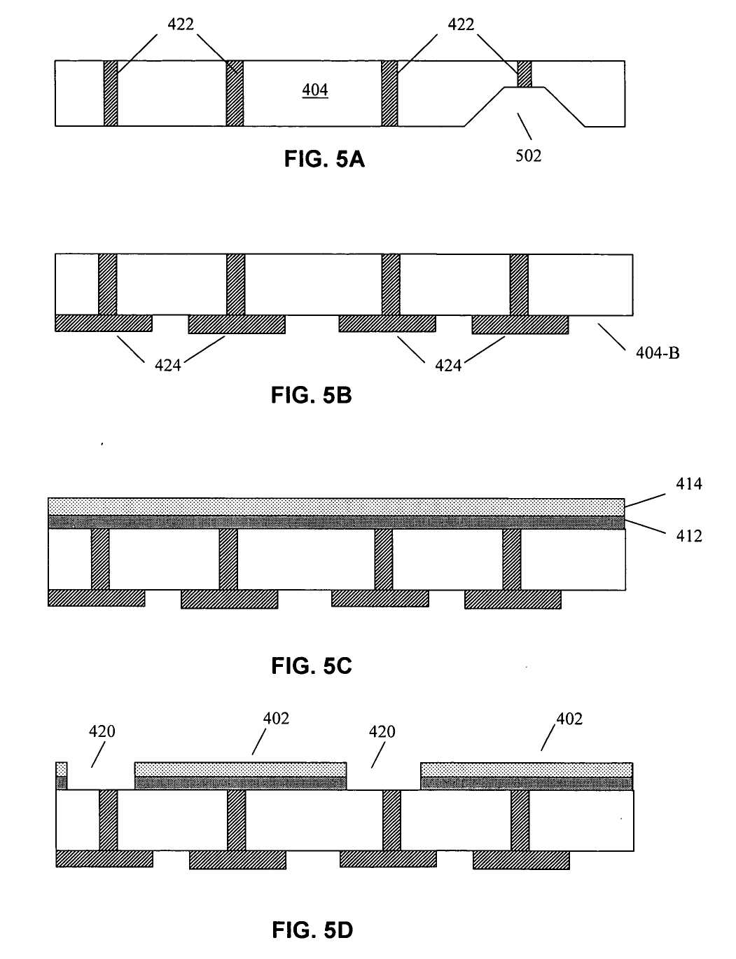

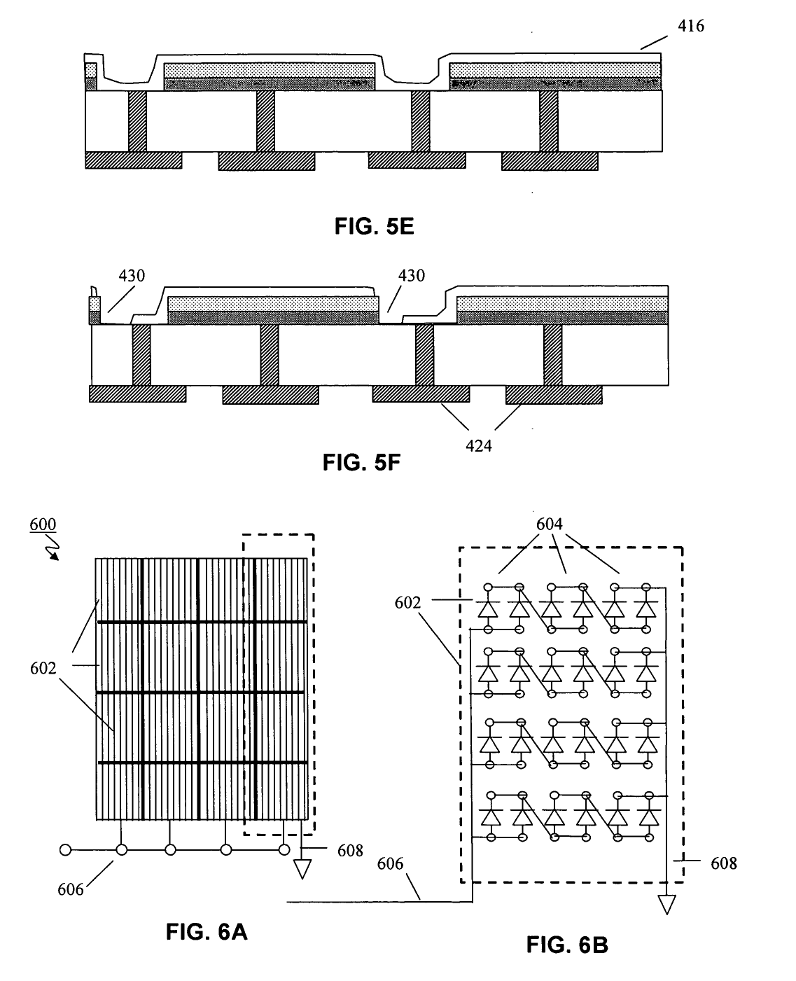

A process flow for fabricating a module such as that shown in FIGS. 4A and 4B generally has two stages: substrate preparation and cell fabrication. Such a process flow is illustrated in more detail in FIGS. 5A to 5F.

FIGS. 5A and 5B illustrate steps for preparing the substrate. As shown in FIG. 5A, the first step of substrate preparation includes forming the via holes and filling them with a conductor. The via holes can be formed in many different ways. In one embodiment, for example, the holes are laser drilled. In another example, the glass substrates are molded with the holes. In yet another example, a mould is used to provide thin areas 502 at the via sites, and the vias are then drilled using, for example a CO₂ laser.

The holes may then be plated through with a metal such as copper or nickel. During this plating, the back side may also be coated and then patterned using conventional printed circuit board methods in accordance with the desired interconnections between cells.

In a next step shown in FIG. 5B, the busses 424 are patterned on the back side of the substrate 404 using plating and methods similar to those employed in printed circuit board manufacture. The patterns are formed in accordance with the desired cell interconnections for the module (e.g. series, series-parallel, parallel).

FIGS. 5C to 5F illustrate an example process flow for cell fabrication after substrate preparation is complete.

As shown in FIG. 5C, the back contact and absorber layers 412 and 414 are sequentially deposited over the entire substrate. Next, as shown in FIG. 5D, a laser scribe forms isolation areas 420 to separate this coating into cell areas 402, with the scribe aligned to expose one set of vias 422. Then, in FIG. 5E, the TCO layer 416 is deposited. Finally, as shown in FIG. 5F, a second scribe creates gaps 430 to isolate the cells 402, leaving cells connected to the bus bars 424 through the substrate 404.

In accordance with one aspect of the invention, because additional processing is not needed to form interconnections between cells, the fabrication process described above requires only two laser scribes, rather than the conventional three. This reduces line width, as fewer scribes must be registered to one another, as well as reducing process complexity. Moreover, unlike the prior art process, the scribes do not require selectivity, and can be done from the front.

It should be noted that other fabrication processing methods, such as those using etch and deposition techniques rather than laser scribes, can be used to form and isolate cells.

It should be further noted that the wiring layer principles of the invention are not limited to the back surface embodiments shown in FIGS. 4B and 5, but can be extended to include alternative arrangements with respect to the substrate and the cell layer.

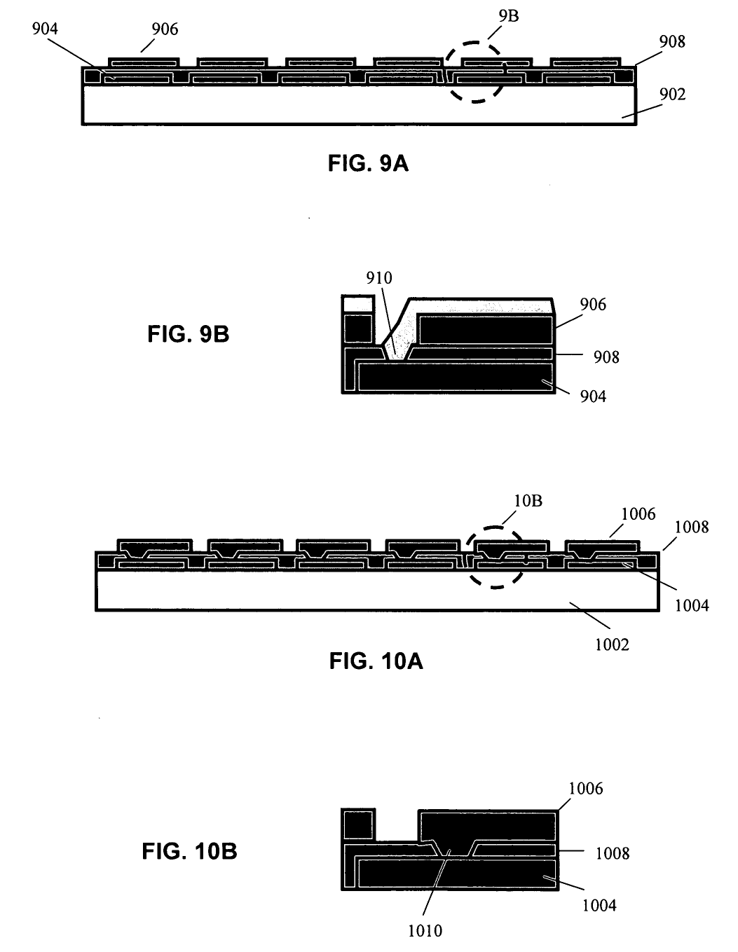

For example, FIGS. 9A and 9B illustrate a first alternative embodiment in which a wiring layer or plane 904 is patterned on a top surface of a substrate 902, and is separated from a cell layer or plane 906 by an insulator layer 908. As shown more particularly in FIG. 9B, vias 910 can then be formed through insulator layer 908 to provide connections (e.g. using a TCO such as ZnO) between the layers. An advantage of this embodiment is that only one surface of the substrate need be processed, and the wiring layer 904 does not block light impinging on the cell layer 906.

FIGS. 10A and 10B illustrate a second alternative embodiment in which a cell layer or plane 1004 comprised of “superstrate” TF PV cells is formed on a top surface of a transparent substrate 1002. In this embodiment, the TF PV cells in layer 1004 convert light impinging on a back surface of substrate 1002 into electrical energy. The wiring layer or plane 1006 is formed above an insulator layer 1008 which is sandwiched between the cell layer 1004 and wiring layer 1006. As shown more particularly in FIG. 10B, vias 1010 can then be formed through insulator layer 1008 to provide direct connections between the layers. Similar to the above embodiment, an advantage of this embodiment is that only one surface of the substrate need be processed, and the wiring layer 1006 does not block light impinging on the cell layer 1004.

According to additional aspects, the teachings of the present invention can be combined with the teachings of co-pending application No. ______ (AMAT-010937) to obtain modules that are even more efficient and less prone to performance degradation due to problems such process non-uniformities and shading, etc.

More particularly, as taught by the co-pending application, the module may be broken into sub-modules, and the cells configured into any series-parallel arrangement of interest. In accordance with the present invention, however, the connection of sub-modules is partially or fully accomplished by patterning busses on the back side of the substrate as taught by the present disclosure.

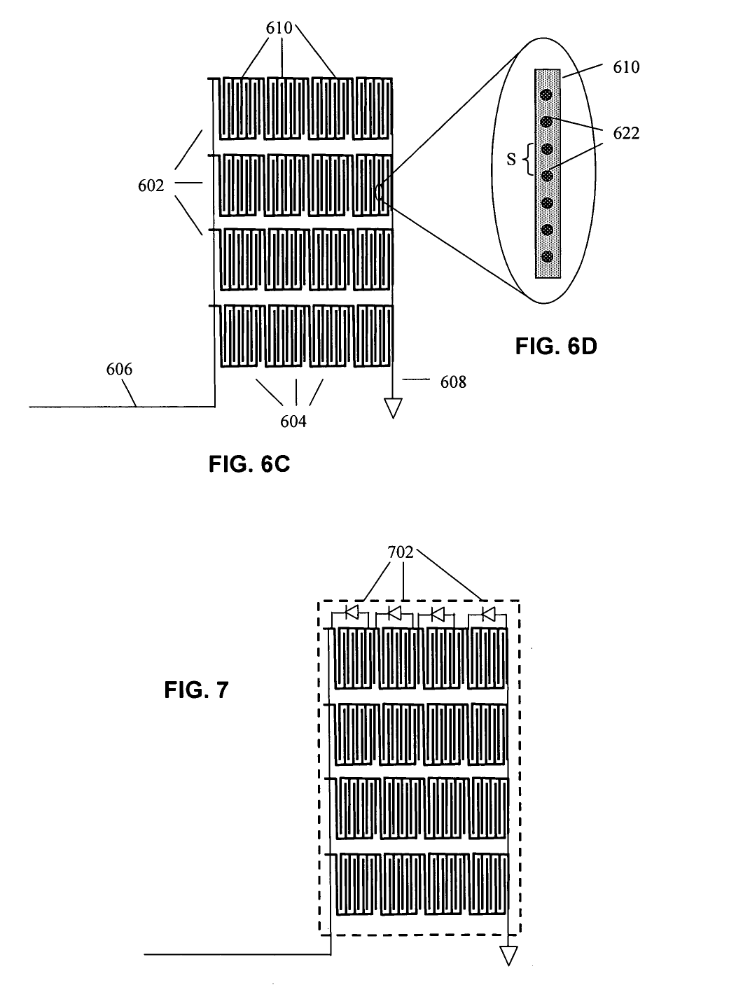

For example, FIG. 6A shows a module 600 broken into 16 sub-modules 602 using laser scribing on the photovoltaic material side to form both vertical and horizontal isolation cuts such as those described in FIGS. 5C to 5F above. Those skilled in the art will appreciate that various divisions into various numbers of sub-modules are possible, that it is not necessary for each set to have the same number of sub-modules, and that the number of sets and the number of sub-modules per set can be different. Moreover, although not shown in detail, in some embodiments, the areas and cells of each sub-module formed by the above process are equal. In other embodiments, the areas of the sub-modules and/or cells therein are varied to account for process variation or other factors.

Vias through the substrate and busses patterned on the back side of the substrate as described above are used to interconnect cells and sub-modules. For example, as schematically shown in FIG. 6B, the cells may be wired in both series and parallel combinations, with sets 604 of adjacent cells wired in parallel and the parallel-connected sets within a sub-module 602 wired in series. All the sub-modules 602 are then wired together in parallel between common first (e.g. output) terminal 606 and second (e.g. ground) terminal 608.

FIG. 6C illustrates how the back side of the substrate can be patterned to accomplish such a wiring arrangement in more detail. More particularly, in this example, busses 610 wire sets of five adjacent cells together in parallel and the four sets 604 in each sub-module 602 are wired together in series. Additional busses are patterned to wire the sub-modules in parallel between terminals 606 and 608.

FIG. 6D is a blow-up of a small portion of bus bar 610, showing how vias 622 spaced closely apart by a distance S will provide many connections between each cell on the top surface of the substrate to the busses 610 on the back surface.

It should be noted that the back side wiring, being similar to a printed circuit board, can include additional elements not used today in TFPV, including protect diodes to further minimize shading or non-uniformity effects, or in more advanced designs, switches and circuitry to dynamically optimize module output. For example, FIG. 7 shows protect diodes 702 for the top sub-module; in practice these could be used with the other sub-modules as well. Such diodes can be placed using conventional surface-mount methods.

It should be noted that in more advanced designs, other components such as active switches and processors could be mounted on the wiring to monitor the power output of the sub-modules and actively adjust the series-parallel wiring to maximize module output, depending on conditions such as time of day, shading, age of the module, and manufacturing variation between the sub-modules.

It should be noted that not all cell connections need be provided on the back surface of the substrate. The invention allows for some connections to be provided on the top surface with other connections provided on the back surface.

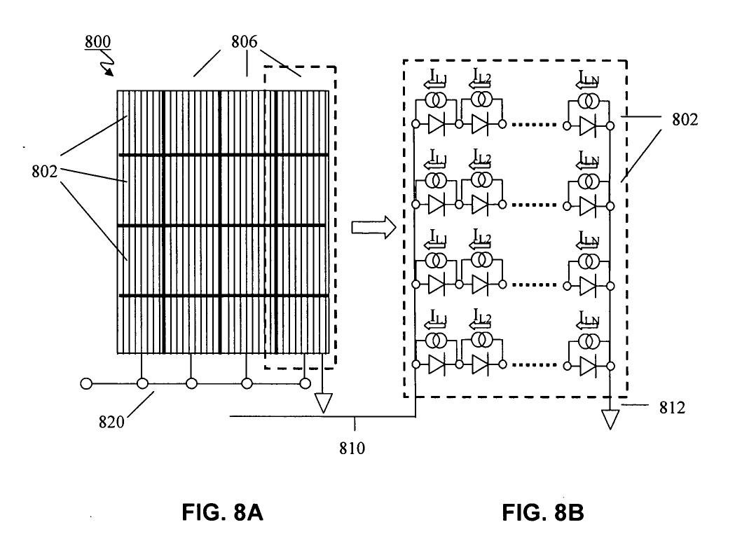

Another example embodiment of the invention will now be described in connection with FIGS. 8A and 8B. In this embodiment, the module is divided into a number of sub-modules and the cells within each sub-module are series connected with wiring on the top surface, while the sub-modules are parallel connected with wiring on the back surface.

One example implementation of this embodiment is shown in FIG. 8A. As shown in this example, the module 800 is divided into 16 sub-modules 802. As further shown in FIG. 8A, the 16 sub-modules 802 are arranged in four sets 806 of four sub-modules each.

An equivalent circuit of one set 806 is shown in FIG. 8B. As shown in FIG. 8B, the cells in each sub-module 802 are series connected, and the series connected sub-modules 802 within each set are connected in parallel. As further shown in FIG. 8B, in this configuration, each sub-module 802 is thus connected between a first (e.g. output) common node 810 and a second (e.g. ground) common node 812. It should be apparent that the sub-modules 802 in the other sets 806 can be similarly configured and connected as shown in FIG. 8B.

Returning to FIG. 8A, the four sets 806 are connected together in parallel. In this example, this is accomplished by connecting the first common node 810 of each set to a common output bus 820.

In one example implementation, the series connection between cells within each sub-module is accomplished using interconnects fabricated on the top surface, for example using the etch and deposition techniques described in co-pending application Ser. Nos. 11/394,723 and 11/395,080. The parallel connections between sub-modules is then accomplished using vias provided through the substrate in the edge areas of each sub-module, and wiring patterned on the back side of the substrate as described in more detail above.

Those skilled in the art will appreciate that a wide range of series and parallel connections and module and sub-module configurations are possible; those shown are only presented as a limited set of examples.

Although the present invention has been particularly described with reference to the preferred embodiments thereof, it should be readily apparent to those of ordinary skill in the art that changes and modifications in the form and details may be made without departing from the spirit and scope of the invention. It is intended that the appended claims encompass such changes and modifications.

What is claimed is:

1. A thin film photovoltaic module comprising:
thin film photovoltaic cells formed in a first layer on a substrate;
interconnections between the cells formed in a second layer on the substrate separate from the first layer.

2. A module according to claim 1, wherein the first layer is on a top surface of the substrate and the second layer is on a back surface of the substrate.

3. A module according to claim 1, wherein the first and second layers are on a top surface of the substrate and separated by an insulating layer.

4. A module according to claim 3, wherein first layer is adjacent the substrate.

5. A module according to claim 1, wherein the substrate is a single layer of material.

6. A module according to claim 1, wherein the substrate comprises two or more layers of different materials.

7. A module according to claim 2, further comprising vias through the substrate that couple the cells to the interconnections.

8. A module according to claim 3, further comprising vias through the insulating layer that couple the cells to the interconnections.

9. A module according to claim 7, wherein the vias are comprised of structures molded in the substrate.

10. A module according to claim 9, where the vias are comprised of laser drilled holes.

11. A module according to claim 9, wherein the vias comprise molded structures in the substrate and laser drilled holes.

12. A module according to claim 9, wherein the vias comprise plated metal.

13. A module according to claim 12, wherein the metal is nickel.

14. A module according to claim 12, wherein the metal is copper.

15. A module according to claim 1, wherein the substrate is glass.

16. A module according to claim 1, wherein the substrate is a polymer material.

17. A module according to claim 2, wherein the substrate is a metal and the vias comprise an insulator to electrically isolate the via from the substrate.

18. A module according to claim 1 wherein the interconnections comprise plated metal.

19. A module according to claim 1, wherein the interconnections wire certain of the cells together in series.

20. A module according to claim 1, wherein the interconnections wire certain of the cells together in parallel.

21. A module according to claim 19, wherein the interconnections wire certain others of the cells together in parallel.

22. A module according to claim 1 further comprising one or more protect diodes coupled between certain of the interconnections.

23. A method of fabricating a thin film photovoltaic module, comprising:
forming interconnects in a first layer on a substrate; and
forming thin film photovoltaic cells in a second layer separate from the first layer on the substrate.

24. A method according to claim 23, wherein the cell forming step includes forming the first layer on a top surface of the substrate and the interconnect forming step includes forming the second layer on a back surface of the substrate.

25. A method according to claim 23, wherein the interconnect and cell forming steps include forming the first and second layers on a top surface of the substrate, the method further comprising forming an insulating layer to separate the first and second layers.

26. A method according to claim 25, wherein first layer is formed adjacent the substrate.

27. A method according to claim 23, wherein the step of forming the interconnects includes patterning the interconnects in accordance with a desired wiring of the cells.

28. A method according to claim 23, further comprising forming vias to connect respective portions of the first and second layers.

29. A method according to claim 24, further comprising forming vias through the substrate.

30. A method according to claim 29, wherein the step of forming the vias include molding structures in the substrate.

31. A method according to claim 29, wherein the step of forming the vias includes laser drilling holes in the substrate.

32. A method according to claim 29, wherein the step of forming the vias includes filling holes in the substrate with plated metal.

33. A method according to claim 23, wherein the step of forming the cells includes at least one laser scribe step.

34. A method according to claim 33 wherein the number of laser scribe steps is greater or equal to two.
